(19) United States
(12) Patent Application Publication
(10) Pub. No.: US 2007/0221982 A1
(43) Pub. Date: Sep. 27, 2007

(54) Semiconductor storage device and method of manufacturing same

(75) Inventor: Yuji Ikeda, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/717,064

(22) Filed: Mar. 13, 2007

(30) Foreign Application Priority Data
Mar. 16, 2006 (JP) 2006-072638

(51) Int. Cl. H01L 29/76

(52) U.S. Cl. 257/314

(57) ABSTRACT

The ratio of capacitance between a floating gate and a control gate to total capacitance in a semiconductor storage device is raised and reliability at read-out is improved by adopting a structure comprising select gates disposed on a substrate in first areas; floating gates disposed in second areas adjacent to the first areas; local bit lines disposed in third areas adjacent to the second areas; and control gates disposed on the floating gates. It is so arranged that capacitance between the select gate and the floating gate is smaller than capacitance between the substrate and the floating gate. It is so arranged that the thickness of a sidewall between the select gate and the floating gate is less than that of an insulating film between the substrate and the floating gate.

### FIELD OF THE INVENTION

This invention relates to a semiconductor storage device having cell transistors and to a method of manufacturing the semiconductor storage device. More particularly, the invention relates to a semiconductor storage device for storing multiple-bit information per cell and to a method of manufacturing the semiconductor storage device.

### BACKGROUND OF THE INVENTION

In semiconductor storage devices according to the related art, a non-volatile semiconductor storage device of the kind illustrated in FIGS. 9 and 10 is known as a non-volatile semiconductor storage device that stores multiple-bit information per cell (Related Art Example 1). The non-volatile semiconductor storage device according to Related Art Example 1 comprises the following in a memory cell: a first diffusion region 107a and a second diffusion region 107b provided in spaced-apart relation on the surface of a substrate 101; a select gate 103a provided on the substrate 101 between the first diffusion region 107a and the second diffusion region 107b via an insulating film 102; and a third diffusion region 121 (FIG. 9) provided on the surface of the substrate 101 below the select gate 103a outside the cell area and extending in a direction that intersects the select gate 103a. Floating gates 106a are provided via the insulating film 102 in a first area between the first diffusion region 107a and the select gate 103a and in a second area between the second diffusion region 107b and the select gate 103a, and control gates 111 are provided on the floating gates 106a and select gate 103a via an insulating film 108. The first diffusion region 107a, floating gate 106a, control gate 111 and select gate 103a construct a first unit cell, and the second diffusion region 107b, floating gate 106a, control gate 111 and select gate 103a construct a second unit cell. An inversion layer 120 is formed on the surface of the substrate 101 below the select gate 103a inside the cell area by applying a positive voltage to the select gate 103a (see Patent Document 1).

In accordance with the non-volatile semiconductor storage device according to Related Art Example 1,

read-out is performed using the channel underlying the select gate 103a as a drain. As a result, without the intermediary of a non-target storage node of one unit cell, read-out is performed from a target storage node of another independent unit cell that opposes the non-target storage mode with the select gate 103a interposed therebetween. Since the device essentially functions as a 1-bit cell, an advantage is that stable circuit operation is obtained.

A method of manufacturing the non-volatile semiconductor storage device according to Related Art Example 1 will be described with reference to the drawings. FIGS. 11A to 14L are process sectional views useful in describing a method of manufacturing the non-volatile semiconductor storage device according to Related Art Example 1.

First, after an element isolation region (not shown) is formed on substrate 101, this is followed by forming a well (not shown) in the cell area of the substrate 101, forming the third diffusion region 121 (FIG. 9), then forming the insulating film 102 (e.g., silicon oxide film) on the substrate, forming a select gate film 103 (e.g., polysilicon film containing a high-concentration impurity) on the insulating film 102, forming an insulating layer 110 on the select gate film 103, forming the insulating film 104 (e.g., silicon nitride film) on the insulating film 110, forming an insulating film 112 (e.g., silicon oxide film) on the insulating film 104, and forming an insulating film 113 (e.g., silicon nitride film) on the insulating film 112 (step A1; FIG. 11A). This is followed by forming photoresist (not shown), which is for forming the select gate 103a, on the insulating film 113, forming the select gates 103a by selectively etching the insulating film 113, insulating film 112, insulating film 104, insulating film 110 and select gate film 103 (FIG. 11A) using the photoresist as a mask, and then removing the photoresist (step A2; FIG. 11B). This is followed by forming an insulating film 105 (e.g., silicon oxide film produced by thermal oxidation) over the entire surface of the substrate (step A3; FIG. 11C).

This is followed by depositing a polysilicon film 106 (e.g., a polysilicon film) over the entire surface of the substrate (step A4; FIG. 12D). This is followed by forming a sidewall-shaped floating gate 106a on the side walls of the insulating film 102, select gate 103a and insulating films 104, 112 and 113 (step A5; FIG. 12E). This is followed by injecting ions into the substrate 101 using the insulating film 105 and floating gate 106 as a mask, thereby forming the first diffusion region 107a and second diffusion region 107b by self-alignment (step A6; FIG. 12F).

This is followed by depositing the insulating film 109 (e.g., CVD silicon oxide film) over the entire surface of the substrate (step A7; FIG. 13G). This is followed by leveling the insulating film 109 (removing the insulating film 105 on the insulating film 113) by the CMP method using the insulating film 113 as a stopper (step A8; FIG. 13H). This is followed by partially removing the insulating film 109 selectively (step A9; FIG. 13I).

This is followed by selectively removing the insulating film (113 in FIG. 13I) (step A10; FIG. 14J). This is followed by selectively removing the insulating film 112 (including part of the insulating films 105 and 109 (step A11; FIG. 14K). It should be noted that part of the insulating film 109 and part of the insulating film 105 also are removed when the insulating film 112 is removed. This is followed by forming the insulating film 108 (e.g., ONO film) over the entire surface of the substrate (step A12; FIG. 14L).

This is followed by depositing a control gate film (e.g., polysilicon) over the entire surface of the substrate, forming a photoresist (not shown), which is for forming a word line, forming the band-shaped second control gate 111 and island-shaped floating gate 106a by selectively removing the control gate film, insulating film 108 and floating gate 106a using the photoresist as a mask, and then removing the photoresist (step A13; FIG. 10). As a result, a semiconductor storage device having a memory cell can be obtained.

The read-out operation of the non-volatile semiconductor storage device according to Related Art Example 1 will be described with reference to the drawings. FIG. 15 is a schematic view useful in describing the read-out operation of the semiconductor storage device according to Related Art Example 1 (the read-out operation when a state in which electrons have not accumulated in a floating gate prevails).

[Patent Document 1] Japanese Patent Application Kokai Publication No. JP-P2005-51227A

[Patent Document 2] Japanese Patent Application Kokai Publication No. JP-P2003-168748A

### SUMMARY OF THE DISCLOSURE

The disclosures of the above patent Documents are incorporated herein by reference thereto.

According to the present invention, the following analysis will be given on the operation.

With regard to the read-out operation, as illustrated in FIG. 15, a positive voltage is applied to the control gate 111, select gate 103a and third diffusion region 121 (FIG. 9) in a state in which electrons have not accumulated in the floating gate 106a (the erase state: threshold-value voltage low, ON cell), whereby electrons e travel from the second diffusion region 107b through the channel immediately underlying the floating gate 106a, travel through the inversion layer 120 formed below the select gate 103a and migrate to the third diffusion region 121 (FIG. 9). In a state in which electrons have accumulated in the floating gate 106a (the write state: threshold-value voltage high, OFF cell), on the other hand, there is no channel below the floating gate 106a and, hence, no flow of electrons e even if a positive voltage is applied to the control gate 111, select gate 103a and third diffusion region 121 (FIG. 9). Read-out is performed by discriminating data (0/1) based upon whether or not the electrons e flow.

At the step A3 of forming the insulating film 105 (see FIG. 11C), the insulating film 105 is formed by ordinary thermal oxidation of the entire surface of the substrate. Owing to accelerated oxidation of the select gate 103a (polysilicon film including impurities in high concentration), the thickness of the insulating film 105 on the side surface of the select gate 103a becomes greater than that of the insulating film 105 on the surface of the substrate 101. If accelerated oxidation of the select gate 103a (polysilicon film containing impurities in high concentration) by thermal oxidation occurs, a bird's beak 105a is formed below the select gate 103a (see FIG. 16). When the cell is large in size (when the select gate 103a has a large width), no problems arise even if the bird's beak 105a is formed below the select gate 103a. However, if the width of the select gate 103a diminishes (e.g., to less than 100 nm) as cell size becomes very small, bird's beaks 105a beneath the select gate 103a to the left and right thereof connect, thereby degrading the shape of (thickening) the gate insulating film below the select gate 103a. Hence there is the danger that the desired operating characteristics will no longer be obtained (see FIG. 16). Accordingly, at the step A3 of forming the insulating film 105 (see FIG. 11C), using the ISSG (in-situ steam generation) oxidation method makes it possible to suppress accelerated oxidation of the select gate 103a and the formation of the bird's beaks 105a. ISSG oxidation is a method of performing oxidation at high temperature and in a short time using a lamp annealer. By adding hydrogen, oxidation proceeds with the hydrogen acting as a catalyst. As a result, the rate of oxidation increases, film quality is improved and bird's beaks tend not to penetrate.

If accelerated oxidation of the select gate 103a is suppressed using the ISSG oxidation method at the step A3 of forming the insulating film 105 (see FIG. 11C), the thickness of the insulating film 105 at the side face of the select gate 103a diminishes in comparison with that when the thermal oxidation method is used, and the thickness becomes approximately equal to the film thickness of the insulating film 105 on the substrate 101. As a result, a capacitance between the select gate 103a and floating gate 106a becomes too large to be ignored. Consequently, there is a decline in the ratio of a capacitance (the capacitance ratio) between the control gate 111 and floating gate 106a to an overall capacitance relating to the floating gate 106a.

Further, by reducing the thickness of the select gate 103a, the capacitance between the select gate 103a and floating gate 106a can be reduced. As a result, however, the thickness of the gates (not shown) of transistors in a peripheral circuit (not shown) at the periphery of the memory cell and the thickness of the select gates 103a cannot be made the same. Consequently, the gates (not shown) of the transistors of the peripheral circuit (not shown) of select gates 103a are formed at a separate step or a step of reducing the thickness of the select gates 103a is required. This leads to an increase in the number of manufacturing steps and means that cost cannot be reduced.

Furthermore, if the thickness of the insulating film 105 on the side surface of the select gate 103a is small, then electrons that have accumulated within the floating gate 106a tend to be pulled out to the select gate 103a owing to the potential of the select gate 103a at the time of the read-out operation. As a consequence, there is a decline in operational reliability (the read-disturb characteristic).

Accordingly, in one aspect of the present invention, it is an object to improve the ratio of capacitance between a floating gate and control gate to the overall capacitance of a memory cell, and to enhance reliability at the time of the read-out operation. Objects in further aspects of the present invention will become apparent from the entire disclosure including appended claims and drawings.

According to a first aspect of the present invention, there is provided a semiconductor storage device comprising: a select gate disposed on a substrate in a first area; a floating gate disposed in a second area adjacent to the first area; a local bit line disposed in a third area adjacent to the second area; and a control gate disposed on the floating gate; it being so arranged that a capacitance between the select gate and the floating gate is smaller than a capacitance between the substrate and the floating gate.

According to a second aspect of the present invention, there is provided a method of manufacturing a semiconductor storage device, comprising the steps of: forming a sidewall-shaped first insulating film on a side wall of a select gate disposed in a first area on a substrate; forming a second insulating film in a second area on the substrate adjacent to the first area; and forming a sidewall-shaped floating gate on the second insulating film and on the side wall of the select gate via the first insulating film; wherein at any step of the foregoing steps, the method is so implemented that a capacitance between the substrate and the floating gate will exceed a capacitance between the select gate and the floating gate.

In the first aspect, the following modes may be implemented.

Spacing between the select gate and the floating gate is greater than spacing between the substrate and the floating gate.

It is so arranged that an opposing area between the select gate and the floating gate is less than an opposing area between the substrate and the floating gate.

The semiconductor storage device further comprises a first insulating film disposed between the select gate and the floating gate; and a second insulating film disposed between the substrate and the floating gate.

The first insulating film has a thickness greater than film thickness of the second insulating film.

The first insulating film is formed of a material having a specific inductivity lower than that of a material used for the second insulating film.

The first insulating film is formed in the shape of a sidewall so as to cover a side wall of the select gate.

The device further comprises a third insulating film disposed on the select gate; wherein the first insulating film covers a part or all of a side wall of the third insulating film.

The device further comprises a fourth insulating film disposed on the third insulating film; wherein the first insulating film covers a part or all of a side wall of the fourth insulating film.

The select gate comprises first select gate members and second select gate members, the first elect gate members extending in a plurality of first comb-like teeth extending from a first common line; the second select gate members extending in a plurality of second comb-like teeth extending from a second common line, the comb-like teeth of the first select gate members being arranged at prescribed intervals inside gaps formed between the second comb-like teeth of the another select gate members in such a manner that the first and second comb-like teeth intermesh each other; the control gate extends in a direction that intersects the comb-like teeth of the select gate and three-dimensionally intersects the select gate; the floating gate comprises floating gate members disposed below the control gate on both sides of the select gate; and the local bit line comprises local bit line members disposed between the comb-like teeth of the select gate along the direction in which the comb-like teeth of the select gate extend.

In the second aspect of the present invention, the following modes may be implemented.

At a step of the forming the second insulating film, the method is so implemented that the second insulating film will have a thickness less than film thickness of the first insulating film at a location directly alongside the select gate.

At a step of the forming the second insulating film, the method is so implemented that the second insulating film is formed of a material having a specific inductivity higher than that of a material used for forming the first insulating film.

At a step of the forming the floating gate, a floating gate film that has been deposited over the entire surface of the substrate inclusive of the first and second insulating films is formed by etch-back.

At a step of the forming the floating gate, the etch-back is adjusted in such a manner that an opposing area between the substrate and the floating gate will be greater than an opposing area between the select gate and the floating gate.

The meritorious effects of the present invention are summarized as follows.

In accordance with the present invention (aspects 1 and 2 and claims 1 to 15), the capacitance between the floating gate and the select gate is less than that between the floating gate and the substrate. As a result, the ratio of the capacitance between the floating gate and the select gate is diminished and the ratio of capacitance between the control gate and floating gate to the total capacitance is raised. Further, the electrons that have accumulated within the floating gate are not readily pulled out to the select gate by the voltage of the select gate at the time of the read-out operation. This improves operational reliability (the read-disturb characteristic). Furthermore, even if the select gate is increased in film thickness and the opposing area (i.e., area constituting capacitor) between the floating gate and select gate is increased, the ratio of capacitance between the control gate and floating gate to the total capacitance does not readily decline. This raises the degree of freedom of design with regard to film thickness of the select gate.

Other features and advantages of the present invention will be apparent from the following description taken in conjunction with the accompanying drawings, in which like reference characters designate the same or similar parts throughout the figures thereof.

Drawing reference characters appended to the subsequent description are solely for assistance in understanding the invention and are not intended to limit the invention to the form illustrated in the drawings.

### BRIEF DESCRIPTIONS OF THE DRAWINGS

FIG. 1 is a partial plan view schematically illustrating the structure of a semiconductor storage device according to a first example of the present invention;

FIG. 2 is a partial sectional view along line X-X′ of FIG. 1 schematically illustrating the structure of the semiconductor storage device according to the first example;

FIGS. 3A to 3C are first process sectional views illustrating a method of manufacturing the semiconductor storage device according to the first example;

FIGS. 4D to 4E are second process sectional views illustrating a method of manufacturing the semiconductor storage device according to the first example;

FIGS. 5G to 5I are third process sectional views illustrating a method of manufacturing the semiconductor storage device according to the first example;

FIGS. 6J to 6K are fourth process sectional views illustrating a method of manufacturing the semiconductor storage device according to the first example;

FIGS. 7M and 7N are fifth process sectional views illustrating a method of manufacturing the semiconductor storage device according to the first example;

FIG. 8 is a partial plan view schematically illustrating an example of a selected cell and an unselected cell in the semiconductor storage device according to the first example;

FIG. 9 is a partial plan view schematically illustrating the structure of a semiconductor storage device according to a first example of the related art;

FIG. 10 is a partial sectional view along line Y-Y′ of FIG. 9 schematically illustrating the structure of the semiconductor storage device according to the first example of the related art;

FIGS. 11A to 11C are first process sectional views illustrating a method of manufacturing the semiconductor storage device according to the first example of the related art;

FIGS. 12D to 12F are second process sectional views illustrating a method of manufacturing the semiconductor storage device according to the first example of the related art;

FIGS. 13G to 13I are third process sectional views illustrating a method of manufacturing the semiconductor storage device according to the first example of the related art;

FIGS. 14J to 14L are fourth process sectional views illustrating a method of manufacturing the semiconductor storage device according to the first example of the related art;

FIG. 15 is a schematic view, as analyzed by the present invention, useful in describing the read-out operation of the semiconductor storage device (the read-out operation when a state in which electrons have not accumulated in a floating gate prevails) according to the first example of the related art; and

FIG. 16 is a diagram, as analyzed by the present invention, schematically illustrating the manner in which a birds' beak is produced in the process of manufacturing the semiconductor storage device according to the first example of the related art.

### MODES FOR CARRYING OUT THE INVENTION

### First Example

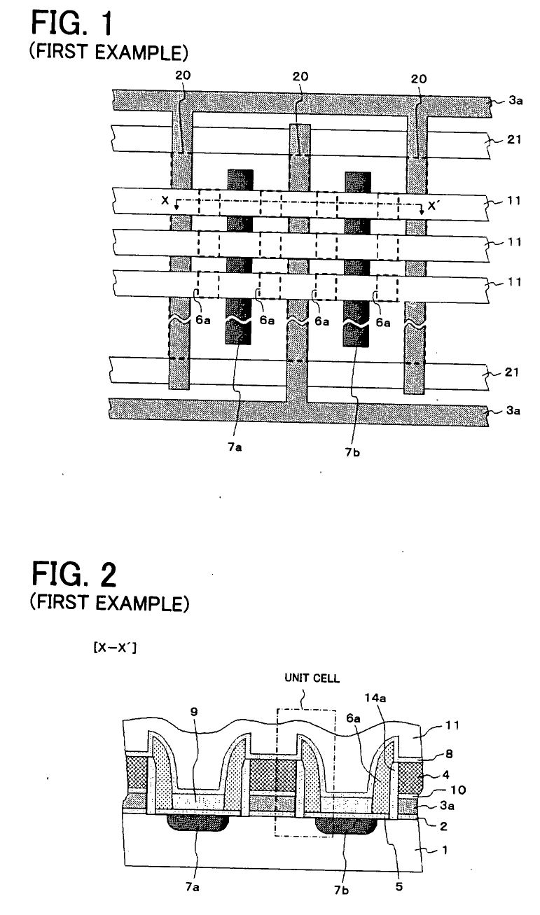

A semiconductor storage device according to a first example of the present invention will now be described with reference to the drawings, in which FIG. 1 is a partial plan view schematically illustrating the structure of the semiconductor storage device according to a first example, and FIG. 2 is a partial sectional view along line X-X′ of FIG. 1 schematically illustrating the structure of the semiconductor storage device according to the first example.

The semiconductor storage device according to the first example is a non-volatile semiconductor storage device that stores 2-bit information per cell. The semiconductor storage device includes a substrate 1, an insulating film 2, a select gate 3a, an insulating film 10, an insulating film 4, an insulating film 5, a side wall 14a, a floating gate 6a, a first diffusion region 7a, a second diffusion region 7b, an insulating film 8, an insulating film 9, a control gate 11 and a third diffusion region 21 (see FIGS. 1 and 2). As indicated by the dot-and-dash line in FIG. 2, one unit cell in the semiconductor storage device comprises one diffusion region, namely the second diffusion region 7b (or the first diffusion region 7a), one floating gate 6a, the control gate 11 and the select gate 3a. A 2-bit cell in the semiconductor storage device is constructed by placing two unit cells in line symmetry sharing the select gate 3a as a common gate.

The substrate 1 is a P-type silicon substrate (see FIGS. 1 and 2). The insulating film 2 is a select-gate insulating film (e.g., silicon oxide film) provided between the select gate 3a and the substrate 1.

The select gate 3a is a conductive film (e.g., polysilicon containing impurities in high concentration) provided on the insulating film 2 (see FIGS. 1 and 2). As seen from the direction of the normal line to the plane of the select gate 3a, the latter extends in a plurality of comb-like teeth from a common line (the horizontal portion in FIG. 1). (First) comb-like teeth of the one select gate 3a are arranged at prescribed intervals inside the gaps between (second) comb-like teeth of another select gate 3a in such a manner that the first teeth intermesh with the second teeth. In order that there will be no increase in manufacturing steps, it is preferred that the film thickness of the select gate 3a be the same as that of the gate (not shown) of a transistor(s) of a peripheral circuit (not shown) located at the periphery of the memory cell area. In order to reduce the capacitance between the select gate 3a and the floating gate 6a, it is preferred that an opposing area (area that constitutes capacitor) between the select gate 3a and floating gate 6a be made smaller than an opposing area (capacitor area) between the substrate 1 and floating gate 6a.

The insulating film 10 is an insulating film (e.g., silicon nitride film) provided on the select gate 3a (see FIG. 2). The insulating film 4 is an insulating film (e.g., silicon nitride film) provided on the insulating film 10. The insulating film 5 is a tunnel insulating film (e.g., silicon oxide film) provided between substrate 1 and the floating gate 6a.

The side wall 14a is a sidewall-shaped tunnel insulating film placed on the substrate 1 and disposed between the side walls of at least the insulating film 2 and select gate 3a and the floating gate 6a. It should be noted that the side wall 14a may be arranged so as to cover a part or all of the side walls of the insulating film 10 and insulating film 4. In order to reduce the capacitance between the select gate 3a and the floating gate 6a, the film thickness of the side wall 14a between the select gate 3a and floating gate 6a should be greater than the film thickness of the insulating film 5, preferably 1.2 to 4 times the film thickness of the insulating film 5, especially 1.5 to 5.3 times the film thickness of the insulating film 5. The film thickness of the side wall 14a between the select gate 3a and floating gate 6a can be adjusted depending upon the etch-back amount (time). Although an insulating film such as a silicon oxide film, for example, can be used as the side wall 14a, a low-k film (e.g., SiOF, BSG, HSQ, SiOC, etc.) exhibiting a specific inductivity lower than that of a silicon oxide film can be used in order to particularly lower the capacitance between the select gate 3a and floating gate 6a.

The floating gate 6a, which is a storage node, is provided via the side wall 14a and insulating film 5 on both sides of the select gate structure comprising a laminate composed of the select gate 3a, insulating film 10 and insulating film 4 (see FIGS. 1 and 2). Polysilicon, for example, can be used as the floating gate 6a. The floating gate 6a is formed in the shape of a side wall when viewed in cross section. The floating gates 6a are disposed in the form of islands when viewed from the direction normal to the plane (see FIG. 1).

The first diffusion region 7a and the second diffusion region 7b are n+ diffusion regions provided in prescribed areas (between neighboring floating gates 6a) of substrate 1 and are disposed between the teeth of the select gate 3a along the direction in which the select gate 3a (the comb-like teeth) extends (see FIGS. 1 and 2). Because of their relationship to the select gate 3a, the first diffusion region 7a and second diffusion region 7b become drain regions of cell transistors at the time of the write operation and source regions at the time of the read-out operation, respectively. The first diffusion region 7a and second diffusion region 7b are also referred to as “local bit lines”. The impurity concentrations of the first diffusion region 7a and second diffusion region 7b are the same.

The insulating film 8 is an insulating film (e.g., an ONO film, which comprises silicon oxide film, silicon nitride film and silicon oxide film and exhibits a high degree of insulation and a high specific inductivity and lends itself to thin-film formation) disposed between the floating gate 6a and the control gate 11. The insulating film 9 is an insulating film [e.g., a silicon oxide film formed by the CVD method or a silicon oxide film (thermal oxide film) produced by thermal oxidation] disposed between the insulating film 8 and the substrate 1 (i.e., between the insulating film 8 and the first diffusion region 7a and second diffusion region 7b of substrate 1) (see FIG. 2).

The control gate 11 controls a channel in the area between the select gate 3 and first diffusion region 7a (second diffusion region 7b). The control gate 11 extends in a direction that intersects (i.e., in a direction perpendicular to) the comb-like teeth of the select gate 3a and three-dimensionally intersects the (first) select gate 3a and the second select gate 3b (see FIGS. 1 and 2). At the portion where it intersects the select gate 3a, the control gate 11 is in abutting contact with the top surface of the insulating film 8 provided on the top layer of the first select gate 3a (see FIG. 2). The control gate 11 is provided via the insulating film 5, floating gate 6 and insulating film 8 on both sides of the select gate structure comprising a laminate composed of the select gate 3a, insulating film 10 and the insulating film 4 (see FIG. 2). The control gate 11 comprises a conductive film, for which polysilicon, for example, can be used. A high-melting-point metal silicide (not shown) may be provided on the surface of the control gate 11 to obtain a low-resistance arrangement.

The third diffusion region 21 is an n+ diffusion region and becomes a source region of the cell transistor at the time of a write operation and a drain region at the time of a read-out operation (see FIG. 1). The third diffusion region 21 extends in a direction that perpendicularly intersects the comb-like teeth of the select gate 3a outside the cell area and three-dimensionally intersects the select gate 3a. At the intersections with the select gate 3a, the third diffusion region 21 is formed (not shown) on the surface of the substrate 1 immediately underlying the insulating film 2 provided in a layer disposed below the select gate 3a.

The write, read and erase operations of the semiconductor storage device according to the first example are similar to those of Related Art Example 1.

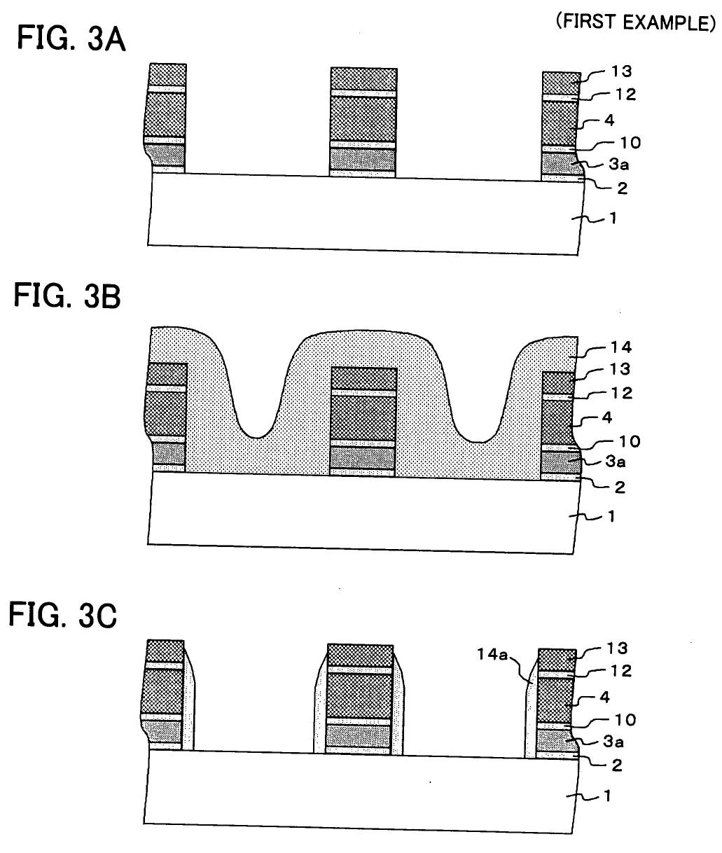

A method of manufacturing the semiconductor storage device according to the first example of the present invention will be described next. FIGS. 3A to 7N are process sectional views schematically illustrating a method of manufacturing the semiconductor storage device according to the first example.

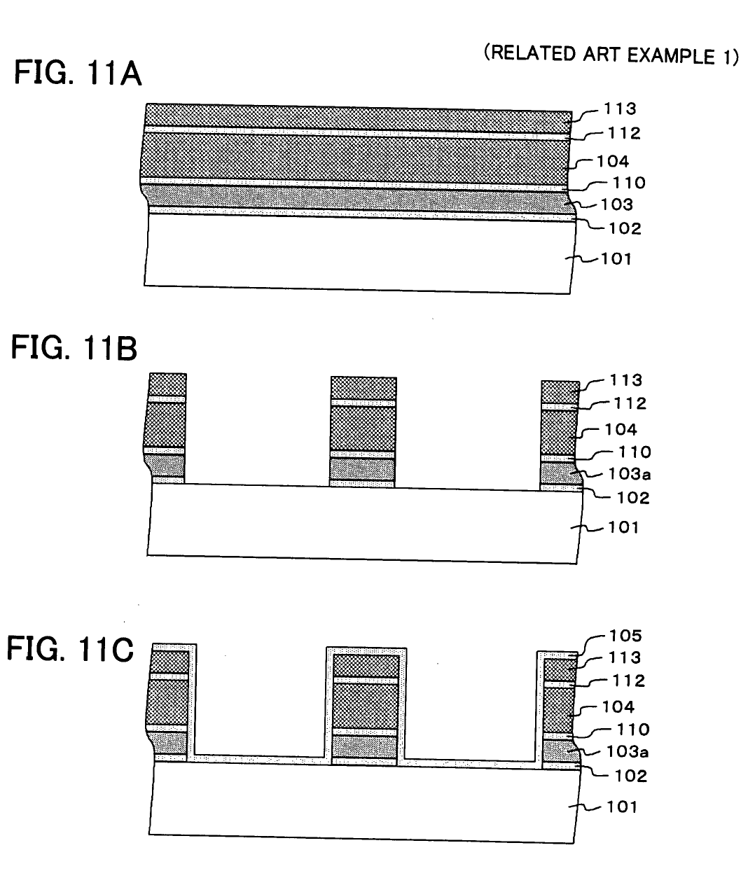

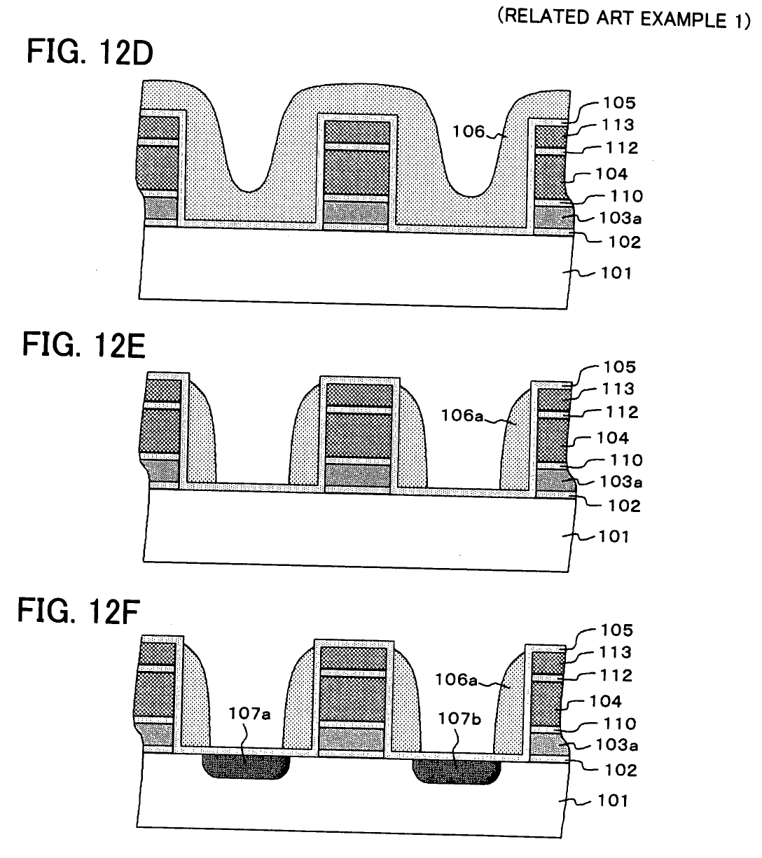

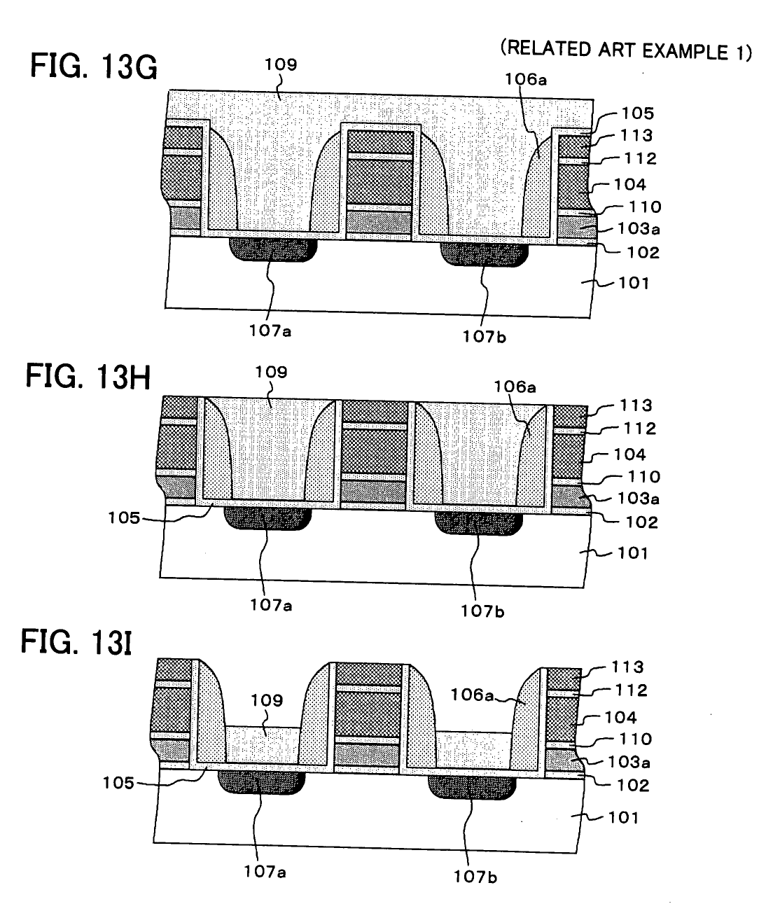

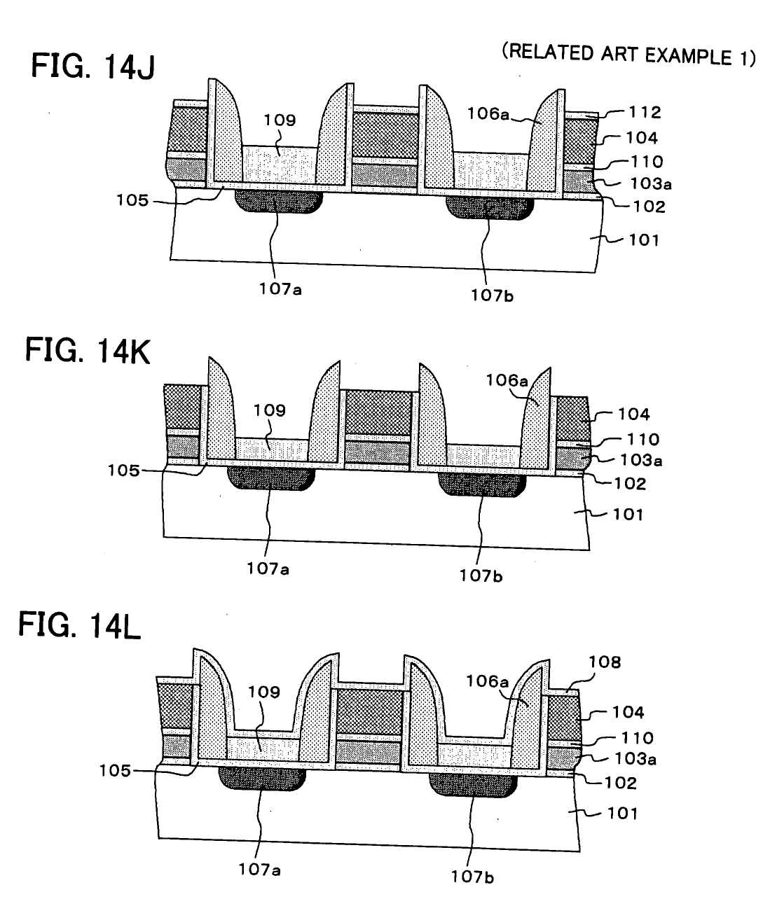

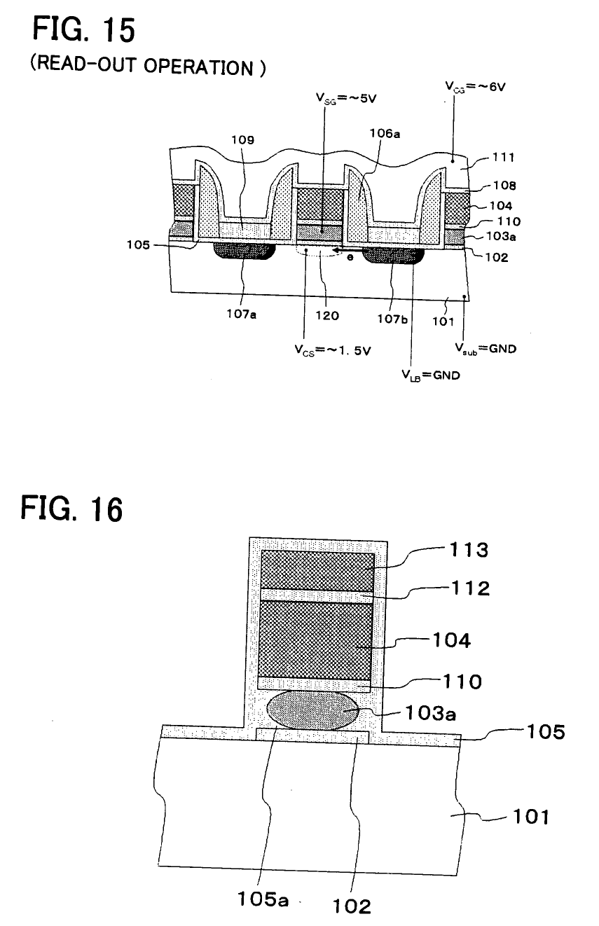

First, the semiconductor storage device having the structure of FIG. 3A is manufactured (step B1) by carrying out the process of steps A1 and A2 of Related Art Example 1 (see FIGS. 11A and 11B). This is followed by depositing an insulating film 14 (e.g., polysilicon film produced by the CVD method or the like) over the entire surface of the substrate (step B2; FIG. 3B). This is followed by forming sidewall 14a on the side walls of at least the insulating film 2 and select gate 3a (it is also possible to include the side walls of the insulating film 10, insulating film 4, an insulating film 12 and an insulating film 13) by performing selective etch-back of the insulating film 14 (FIG. 3B) (step B3; FIG. 3C).

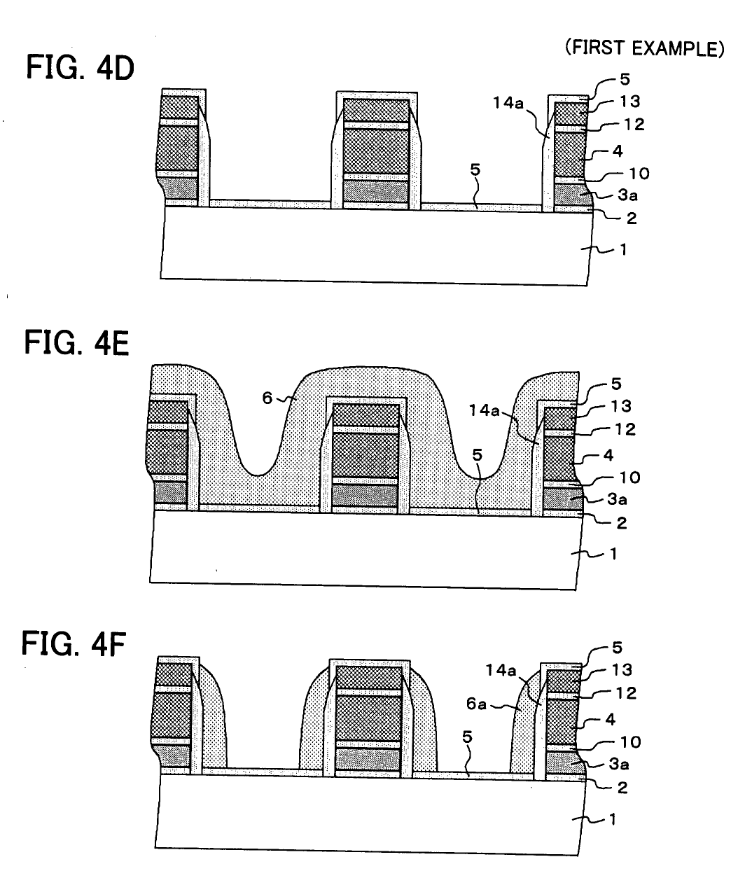

Next, the insulating film 5 (e.g., silicon oxide film produced by thermal oxidation or ISSG oxidation, etc.) is formed over the entire surface of the substrate (sidewall 14a) (step B4; FIG. 4D). This is followed by depositing a floating gate film 6 (e.g., polysilicon film) over the entire surface of the substrate (step B5; FIG. 4). This is followed by forming a sidewall-shaped floating gate 6a, which covers the sidewall 14a, at the side of the insulating film 2, select gate 3a, insulating film 4, insulating film 12 and insulating film 13 by performing etch-back of the floating gate film 6 (FIG. 4D) (step B6; FIG. 4F).

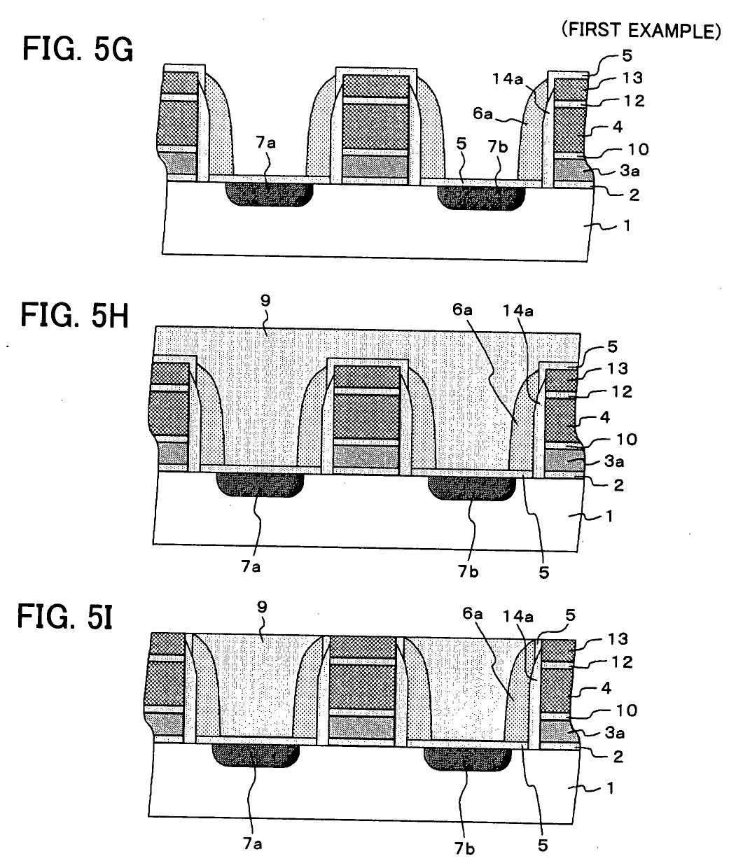

This is followed by injecting ions into the substrate 1 using the insulating film 5 and floating gate 6a as a mask, thereby forming the first diffusion region 7a and second diffusion region 7b by self-alignment (step B7; FIG. 5G). This is followed by depositing the insulating film 9 (e.g., CVD silicon oxide film) over the entire surface of the substrate (step B8; FIG. 5H). This is followed by leveling the insulating film 9 (removing the insulating film 5 on the insulating film 13) by the CMP method using the insulating film 13 as a stopper (step B5; FIG. 5I).

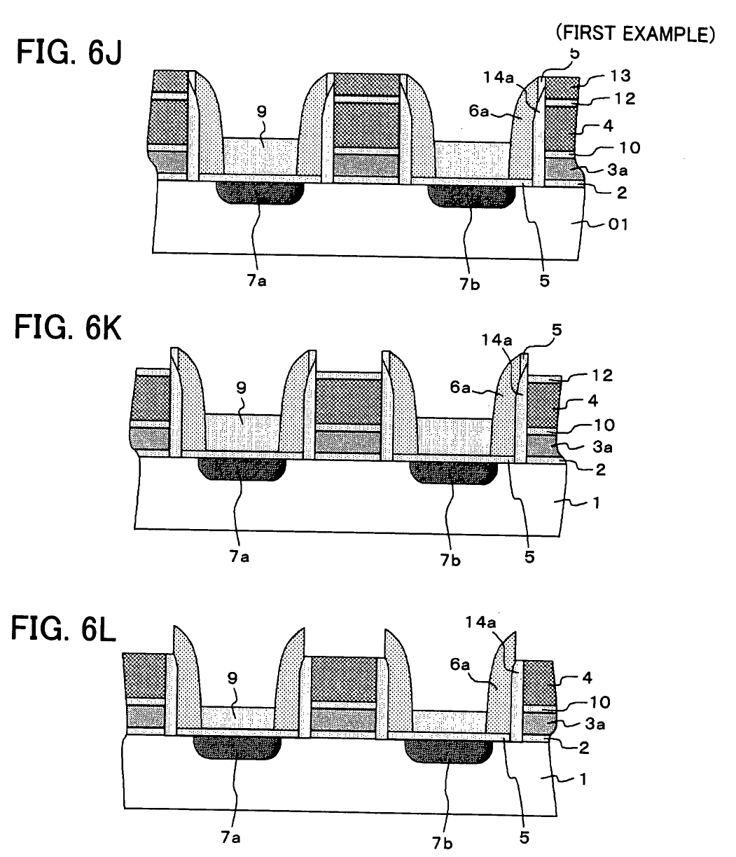

This is followed by partially removing the insulating film 9 selectively (step BIO; FIG. 6J). This is followed by selectively removing the insulating film 13 (FIG. 6J) (step B11; FIG. 6K). This is followed by selectively removing the insulating film 12 (step B12; FIG. 6L). It should be noted that when the insulating film 12 is removed, part of the insulating film 9 and part of the insulating film 5 also are removed and there are cases where part of the sidewall 14a also is removed.

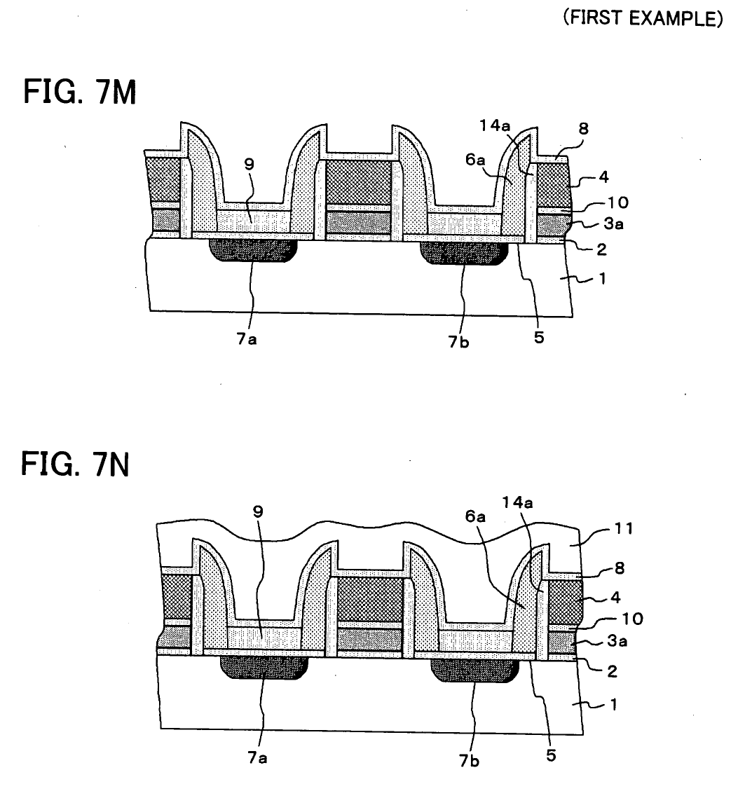

This is followed by forming the insulating film 108 (e.g., ONO film) over the entire surface of the substrate (step B13; FIG. 7M). This is followed by depositing a control gate film (e.g., polysilicon) over the entire surface of the substrate, forming a photoresist (not shown), which is for forming a word line, forming the band-shaped second control gate 11 and island-shaped floating gate 6a by selectively removing the control gate film, insulating film 8 and floating gate 6a using a photoresist as a mask, and then removing the photoresist (step B14; FIG. 7N). As a result, a semiconductor storage device having the sidewall 14a between the select gate 3a and floating gate 6a can be achieved.

In accordance with the first example, the film thickness of the sidewall 14a (insulating film) between the floating gate 6a and select gate 3a is greater than the film thickness of the insulating film 5 between the floating gate 6a and substrate 1. As a result, capacitance C_{sf} between the floating gate 6a and select gate 3a is reduced and a ratio (CR_{cf}) of capacitance between the control gate 11 and floating gate 6a to the total capacitance is raised.

Further, the film thickness of the sidewall 14a (insulating film) between the floating gate 6a and select gate 3a is greater than the film thickness of the insulating film 5 between the floating gate 6a and substrate 1. Accordingly, the electrons that have accumulated within the floating gate 6a are not readily pulled out to the select gate 3a by the voltage of the select gate 3a at the time of the read-out operation. This improves operational reliability (resistance to the read-disturb).

Furthermore, even if the select gate 3a is increased in film thickness and the opposing area (capacitor area) between the floating gate 6a and select gate 3a is increased, the ratio (CR_{cf}) of capacitance between the control gate 11 and floating gate 6a to the total capacitance does not readily decline. This raises the degree of freedom of design with regard to the film thickness of the select gate 3a.

Described next will be the principle whereby the capacitance between the select gate 3a and floating gate 6a is reduced, thereby raising the ratio of capacitance between the control gate 11 and floating gate 6a to the overall capacitance.

The ratio (CR_{cf}) of capacitance between the control gate 11 and floating gate 6a to the total capacitance (Call) can be calculated according to Equation (1) below. It should be noted that C_{cf} represents the capacitance between the control gate 11 and floating gate 6a, C_{sf} the capacitance between the select gate 3a and floating gate 6a and C_{fsub} the capacitance between the floating gate 6a and substrate 1.

$$CRcf = \frac{Ccf}{Call} \\ Call = Ccf + Csf + Cfsub \qquad Equation ( 1 )$$

Accordingly, reducing C_{cf} improves CR_{cf} and improves the sensitivity of potential V_{fg} of floating gate 6a to voltage V_{cg} of the control gate 11.

In a case where the influence of voltage V_{sg} of the select gate 3a is taken into consideration, the potential V_{fg} of floating gate 6a can be calculated according to Equation (2) below. Here V_{sub} represents the voltage of substrate 1.

$$( Vcg - Vfg ) \cdot Ccf + ( Vsg - Vfg ) \cdot Csf + ( Vsub - Vfg ) \cdot Csub = 0 \\ Vfg = \frac{Vcg \cdot Ccf + Vsg \cdot Csf + Vsub \cdot Cfsub}{Ccf + Csf + Cfsub} \qquad Equation ( 2 )$$

When cell read-out is performed, a positive voltage is applied to V_{cg} and V_{sg}. Since V_{sub} is 0 V, the potential V_{fg} of floating gate 6a can be calculated according to Equation (3) below.

$$Vfg = \frac{Vcg \cdot Ccf + Vsg \cdot Csf}{Ccf + Csf + Cfsub} \qquad Equation ( 3 )$$

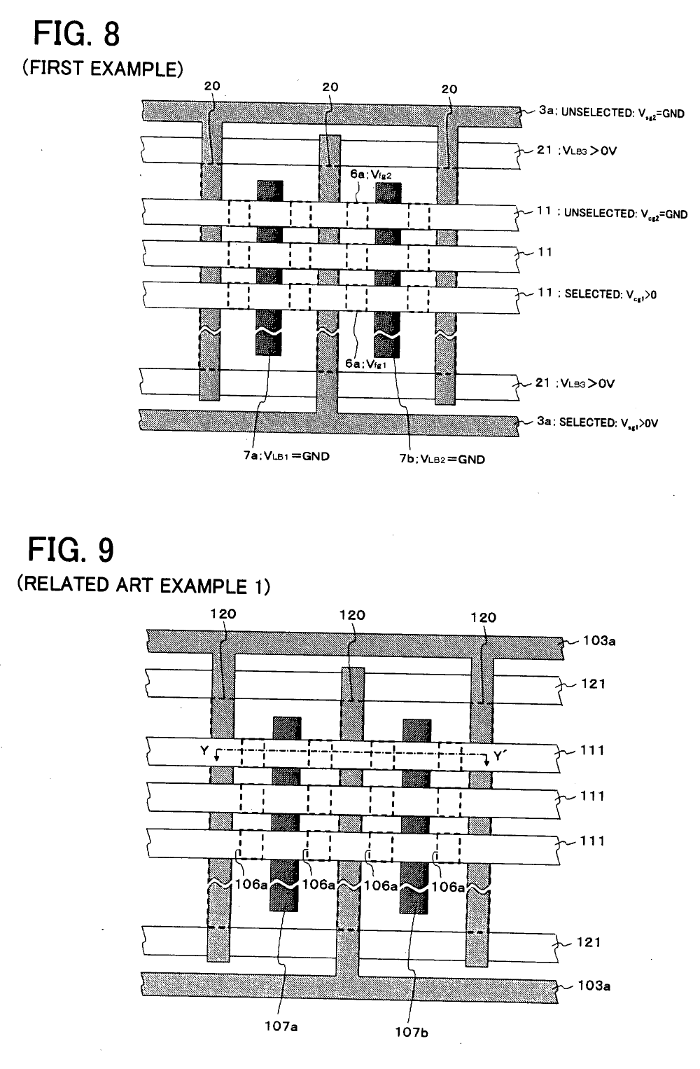

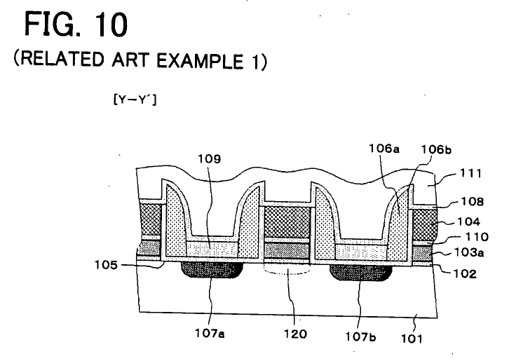

Potential V_{fg1} of the floating gate 6a regarding the selected control gate 11 of voltage V_{cg1} (>0) and selected select gate 3a of voltage V_{sg1} (>0) at this time is as indicated by Equation (4) below (see FIG. 8).

$$Vfg 1 = \frac{Vcg 1 \cdot Ccf + Vsg 1 \cdot Csf}{Ccf + Csf + Cfsub} \qquad Equation ( 4 )$$

Further, potential V_{fg2} of the floating gate 6a regarding the unselected control gate 11 of voltage V_{cg2} (=0) and selected select gate 3a of voltage V_{sg1} (>0) at this time is as indicated by Equation (5) below (see FIG. 8).

$$Vfg 2 = \frac{Vsg 1 \cdot Csf}{Ccf + Csf + Cfsub} \qquad Equation ( 5 )$$

Accordingly, the difference between the potential V_{fg1} of the floating gate 6a regarding the selected cell and the potential V_{fg2} of the floating gate 6a regarding the unselected cell is as indicated by Equation (6) below.

$$Vfg 1 - Vfg 2 = \frac{Vcg 1 \cdot Ccf}{Ccf + Csf + Cfsub} \\ Vfg 1 - Vfg 2 = CRcf \cdot Vcg 1 \qquad Equation ( 6 )$$

In other words, even in a case where the voltage V_{sg1} (>0) of the selected select gate 3a is taken into consideration, the sensitivity of the potential of the floating gate 6a to the voltage V_{cg1} of the selected control gate 11 can be expressed by the ratio (CR_{cf}) of capacitance between the control gate 11 and floating gate 6a to the total capacitance. Accordingly, by reducing C_{sf}, CR_{cf} is improved. As a result, read-out sensitivity of the selected cell is improved.

As many apparently widely different examples of the present invention can be made without departing from the spirit and scope thereof, it is to be understood that the invention is not limited to the specific examples thereof except as defined in the appended claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor storage device comprising:
a select gate disposed on a substrate in a first area;
a floating gate disposed in a second area adjacent to the first area;
a local bit line disposed in a third area adjacent to the second area; and
a control gate disposed on said floating gate; wherein
a capacitance between said select gate and said floating gate is smaller than a capacitance between the substrate and said floating gate.

2. The device according to claim 1, wherein spacing between said select gate and said floating gate is greater than spacing between the substrate and said floating gate.

3. The device according to claim 1, wherein it is so arranged that an opposing area between said select gate and said floating gate is less than an opposing area between the substrate and said floating gate.

4. The device according to claim 1, further comprising:
a first insulating film disposed between said select gate and said floating gate; and
a second insulating film disposed between the substrate and said floating gate.

5. The device according to claim 4, wherein said first insulating film has a thickness greater than film thickness of said second insulating film.

6. The device according to claim 4, wherein said first insulating film is formed of a material having a specific inductivity lower than that of a material used for said second insulating film.

7. The device according to claim 4, wherein said first insulating film is formed in the shape of a sidewall so as to cover a side wall of said select gate.

8. The device according to claim 4, further comprising a third insulating film disposed on said select gate;
wherein said first insulating film covers a part or all of a side wall of said third insulating film.

9. The device according to claim 8, further comprising a fourth insulating film disposed on said third insulating film;
wherein said first insulating film covers a part or all of a side wall of said fourth insulating film.

10. The device according to claim 1, wherein said select gate comprises first select gate members and second select gate members, said first select gate members extending in a plurality of first comb-like teeth extending from a first common line; said second select gate members extending in a plurality of second comb-like teeth extending from a second common line, the comb-like teeth of the first select gate members being arranged at prescribed intervals inside gaps formed between the second comb-like teeth of said another select gate members in such a manner that said first and second comb-like teeth intermesh each other;
said control gate extends in a direction that intersects the comb-like teeth of said select gate and three-dimensionally intersects said select gate;
said floating gate comprises floating gate members disposed below said control gate on both sides of said select gate; and
said local bit line comprises local bit line members disposed between the comb-like teeth of said select gate along the direction in which the comb-like teeth of said select gate extend.

11. A method of manufacturing a semiconductor storage device, comprising:
forming a sidewall-shaped first insulating film on a side wall of a select gate disposed in a first area on a substrate;
forming a second insulating film in a second area on the substrate adjacent to the first area; and
forming a sidewall-shaped floating gate on the second insulating film and on the side wall of the select gate via the first insulating film;
wherein at any step of the foregoing steps, said method is so implemented that a capacitance between the substrate and the floating gate will exceed a capacitance between the select gate and the floating gate.

12. The method according to claim 11, wherein at a step of said forming the second insulating film, said method is so implemented that the second insulating film will have a thickness less than film thickness of the first insulating film at a location directly alongside the select gate.

13. The method according to claim 11, wherein at a step of said forming the second insulating film, said method is so implemented that the second insulating film is formed of a material having a specific inductivity higher than that of a material used for forming the first insulating film.

14. The method according to claim 11, wherein at a step of said forming the floating gate, a floating gate film that has been deposited over the entire surface of the substrate inclusive of the first and second insulating films is formed by etch-back.

15. The method according to claim 14, wherein at a step of said forming the floating gate, the etch-back is adjusted in such a manner that an opposing area between the substrate and the floating gate will be greater than an opposing area between the select gate and the floating gate.
